(19) United States
(12) Patent Application Publication
(10) Pub. No.: US 2011/0227040 A1
(43) Pub. Date: Sep. 22, 2011

(54) TEMPERATURE SENSOR AND MANUFACTURING METHOD OF TEMPERATURE SENSOR

(75) Inventors: Takao IWAKI, Miyoshi-city (JP); Hiroyuki Wado, Toyota-city (JP); Yukihiro Takeuchi, Nishikamo-gun (JP)

(73) Assignee: DENSO CORPORATION, Kariya-city (JP)

(21) Appl. No.: 13/043,842

(22) Filed: Mar. 9, 2011

(30) Foreign Application Priority Data
Mar. 11, 2010 (JP) 2010-54931

(51) Int. Cl. H01L 29/66; H01L 21/02

(52) U.S. Cl. 257/14; 438/54; 257/E29.347; 257/E21.002

(57) ABSTRACT

A temperature sensor includes a semiconductor substrate and a quantum well structural part disposed on the semiconductor substrate. The semiconductor substrate is made of a plurality of elements. The quantum well structural part has a resistance value that changes with temperature. The quantum well structural part includes a plurality of semiconductor layers made of the elements. The semiconductor layers include a plurality of quantum barrier layers and a quantum well layer disposed between the quantum barrier layers. When the semiconductor substrate has a lattice constant “a,” each of the quantum barrier layers has a lattice constant “b,” and the quantum well layer has a lattice constant “c,” the semiconductor substrate, the quantum barrier layers, and the quantum well layer satisfy a relationship of b<a<c or c<a<b.

### CROSS REFERENCE TO RELATED APPLICATIONS

The present application is based on and claims priority to Japanese Patent Application No. 2010-54931 filed on Mar. 11, 2010, the contents of which are incorporated in their entirety herein by reference.

### BACKGROUND OF THE INVENTION

1. Field of the Invention

The present invention relates to a temperature sensor and a manufacturing method of a temperature sensor.

2. Description of the Related Art

Japanese Patent No. 3,573,754 (corresponding to U.S. Pat. No. 6,292,089) discloses a structure for a temperature sensor that detects a physical quantity based on a temperature.

The temperature sensor structure disclosed in the above-described document includes a substrate, a thermistor layer supported by the substrate and having a resistance value being dependent on temperature, a first electric contact layer disposed on a first surface of the thermistor layer, and a second electric layer disposed on a second surface of the thermistor layer. The thermistor layer includes a quantum well structural body including a well layers and barrier layers (GaAs/AlGaAs) which are alternately arranged.

In order to improve a sensitivity of a temperature sensor using a quantum well structural body, it is necessary to increase the value of temperature coefficient of resistance (TCR) of the quantum well structural body.

The TCR of the quantum well structural body can be expressed as following equation:

TCR=−1/k_{B}T²×(3k_{B}T/2+V−E_{f})

where “k_{B}” is the Boltzmann constant, “T [k]” is the absolute temperature, “V (=E_{B}−E_{W})” is a barrier energy, “E_{B}” is an energy at a peak of a valence band (or a bottom of a conduction band) of the barrier layers, “E_{W}” is an energy at a peak of a valence band (or a bottom of a conduction band) of the well layers, and “E_{f}” is a Fermi energy. When the well layers are doped with p type impurities, each of “E_{B}” and “E_{W}” means the peak of the valence band, and when the well layers are doped with n type impurities, each of “E_{B}” and “E_{W}” means the bottom of the conduction band.

As shown in the above equation, it is required to increase the barrier energy “V” or decrease the Fermi energy “E_{f}” in order to increase the value of |TCR|.

When a temperature sensor including a quantum well structural body is manufactured with a complementary metal oxide semiconductor (CMOS) process, there are advantages that circuits can be integrally formed easily and noises can be restricted and that the manufacturing cost can be reduced because the temperature sensor can be manufactured in the conventional semiconductor factory. A case where SiGe/Si is used as an example of materials for forming the quantum well structural body, that is, materials for forming the barrier layers and the well layers will be described below. The same discussion can be applied to other materials.

When a material system of SiGe/Si is used, a quantum well generally includes p type doped SiGe and non-doped Si This is because the barrier height of the valence band is larger than the barrier height of the conduction band in this system. As shown in FIG. 13, when a Ge composition ratio in SiGe is indicated by “x,” the barrier height “V” of the valence band can be expressed as V=0.84×[eV]. Thus, when the Ge composition ratio in SiGe increases, the barrier height increases, and the value of |TCR| increases.

In an epitaxial growth of SiGe on Si, there is a critical thickness. Thus, it is difficult to increase the Ge composition ratio freely. When the thickness of SiGe is greater than the critical thickness, a crystal defect is generated for relaxing a strain in SiGe.

As shown in FIG. 14, regarding the critical thickness of SiGe, two theories by Matthews et al. and People et al. are known. In FIG. 14, experimental values by Bean et al. and Yaguchi et al. are also shown. A thickness of SiGe suitable for a temperature sensor including a quantum well structural part, that is, a quantum well structural infrared detector is about 10 nm (100 Å). Thus, the Ge composition ratio with which the SiGe can grow without causing a crystal defect is 0.24 (from the theory by Matthews et al.) or 0.56 (from the theory by People et al.) and it is difficult to form a SiGe layer having a high Ge composition ratio.

### SUMMARY OF THE INVENTION

In view of the foregoing problems, it is an object of the present invention to provide a temperature sensor that can restrict generation of a crystal defect and can have a high sensitivity. Another object of the present invention is to provide a manufacturing method of a temperature sensor.

A temperature sensor according to a first aspect of the present invention includes a semiconductor substrate and a quantum well structural part disposed on the semiconductor substrate. The semiconductor substrate is made of a plurality of elements. The quantum well structural part has a resistance value that changes with temperature. The quantum well structural part includes a plurality of semiconductor layers made of the elements. The semiconductor layers include a plurality of quantum barrier layers and a quantum well layer disposed between the quantum barrier layers. When the semiconductor substrate has a lattice constant “a,” each of the quantum barrier layers has a lattice constant “b,” and the quantum well layer has a lattice constant “c,” the semiconductor substrate, the quantum barrier layers, and the quantum well layer satisfy a relationship of b<a<c or c<a<b.

The temperature sensor according to the first aspect can restrict generation of a crystal defect and can have a high sensitivity.

A manufacturing method according to a second aspect of the present invention is a manufacturing method of a semiconductor device that includes semiconductor substrate and a quantum well structural part disposed on the semiconductor substrate, in which the semiconductor substrate is made of a plurality of elements including an element E₁ and an element E₂, the quantum well structural part has a resistance value that changes with temperature, the quantum well structural part includes a plurality of semiconductor layers made of the plurality, of elements, and the plurality of semiconductor layers includes a plurality of quantum barrier layers and a quantum well layer disposed between the plurality of quantum barrier layers, the manufacturing method includes epitaxially growing the plurality of quantum barrier layers and the quantum well layer on the semiconductor substrate in such a manner that each of the quantum barrier layers has a lower E₂ composition ratio and the quantum well layer has a higher E₂ composition ratio than an E₂ composition ratio of the semiconductor substrate.

The manufacturing method of a temperature sensor according to the second aspect can manufacture a temperature sensor that has a large energy difference between the quantum barrier layers and the quantum well layer and has a high sensitivity.

A manufacturing method according to a third aspect of the present invention is a manufacturing method of a semiconductor device that includes semiconductor substrate and a quantum well structural part disposed on the semiconductor substrate, in which the semiconductor substrate is made of a plurality of elements including an element E₁ and an element E₂, the quantum well structural part has a resistance value that changes with temperature, the quantum well structural part includes a plurality of semiconductor layers made of the plurality of elements, and the plurality of semiconductor layers includes a plurality of quantum barrier layers and a quantum well layer disposed between the plurality of quantum barrier layers, the manufacturing method includes epitaxially growing the plurality of quantum barrier layers and the quantum well layer on the semiconductor substrate in such a manner that each of the quantum barrier layers has a higher E₂ composition ratio and the quantum well layer has a lower E₂ composition ratio than an E₂ composition ratio of the semiconductor substrate.

The manufacturing method of a temperature sensor according to the third aspect can manufacture a temperature sensor that has a large energy difference between the quantum barrier layers and the quantum well layer and has a high sensitivity.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a cross-sectional view of a temperature sensor according to an exemplary embodiment of the present invention;

FIG. 2 is a cross-sectional view of a quantum well structure part in the temperature sensor;

FIG. 3 is a graph showing an improvement of the value of TCR with respect to a difference in Ge composition ratio between barrier layers and a well layer;

FIG. 4 is a graph showing a relationship between a first quantum level and a thickness of the well layer;

FIG. 5 is a graph showing a relationship between the value of |TCR| and the thickness of the well layer;

FIG. 6 is a cross-sectional view showing a process of preparing a SGOI substrate in a manufacturing process of the temperature sensor;

FIG. 7 is a cross-sectional view showing a process of patterning an oxide layer in the manufacturing process of the temperature sensor;

FIG. 8 is a cross-sectional view showing a process of forming a QW structural part in the manufacturing process of the temperature sensor;

FIG. 9 is an enlarged cross-sectional view of a QW structural part in the manufacturing process of the temperature sensor;

FIG. 10 is a cross-sectional view showing a process of forming a SiGe layer in the manufacturing process of the temperature sensor;

FIG. 11 is a cross-sectional view showing a process of forming an oxide layer in the manufacturing process of the temperature sensor;

FIG. 12 is a cross-sectional view showing a process of forming electrodes in the manufacturing process of the temperature sensor;

FIG. 13 is a graph showing a relationship between a Ge composition ratio and energy in SiGe; and

FIG. 14 is a graph showing a relationship between a Ge composition ratio, a thickness, and a lattice mismatch in SiGe.

### DETAILED DESCRIPTION OF THE PREFERRED EMBODIMENTS

An exemplary embodiment of the present invention will be described with reference to the drawings.

A temperature sensor 100 according to the present embodiment detects change in electric current due to change in temperature of a quantum well structural part (QW structural part) 50 and can be suitably used for an infrared sensor. In other words, the temperature sensor 100 includes the QW structural part that functions as a detecting part whose resistance changes with temperature. In other words, the temperature sensor 100 is a quantum well structural infrared detector. Because the value of |TCR| of the temperature sensor 100 is large, the temperature sensor 100 can be used for detecting infrared ray with a high sensitivity.

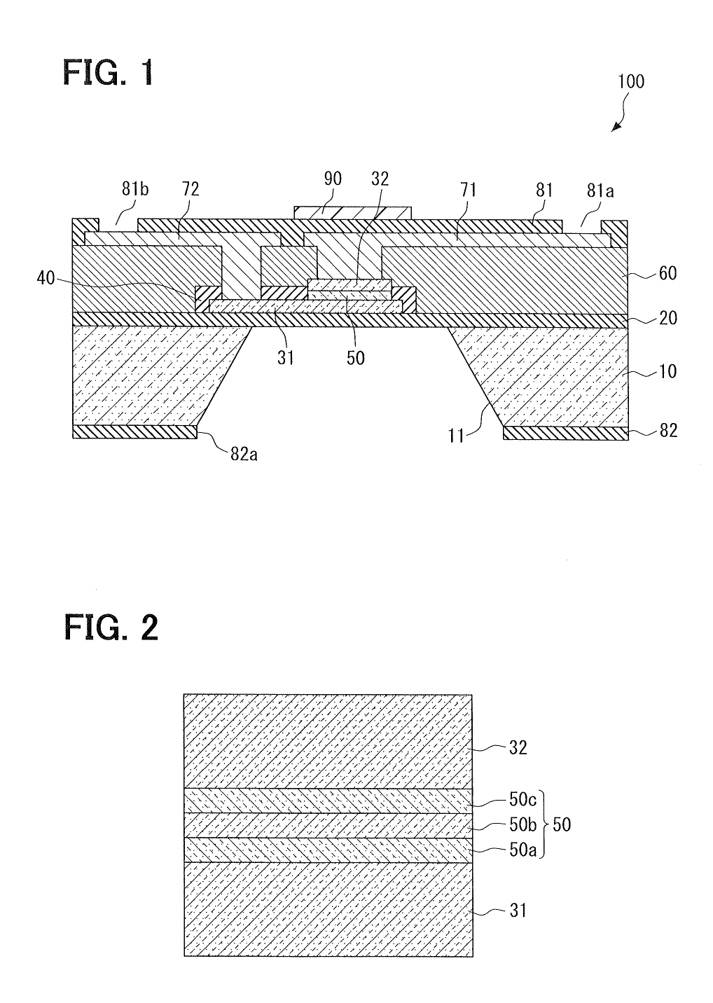

As shown in FIG. 1, the temperature sensor 100 according to the present invention includes a Si substrate 10. The Si substrate 10 can function as a support substrate. The Si substrate 10 has an opening portion 11, and membrane is formed at a portion where the opening portion 11 is provided.

The opening portion 11 is provided so as to penetrate the Si substrate 10 from a rear surface to a front surface. Specifically, the opening portion 11 is provided in such a manner that an opening area decreases in a direction from the rear surface to the front surface of the Si substrate 10.

On the front surface of the Si substrate 10, an oxide layer 20 made of, for example, SiO₂ is disposed. The oxide layer 20 can function as an insulating layer. The membrane is provided by a part of the oxide layer 29 located above the opening portion 11. On the front surface of the oxide layer 20, a SiGe layer 31 is disposed. The SiGe layer 31 can function as a semiconductor substrate made of a plurality of elements. The SiGe layer 31 needs to be a semiconductor layer made of a plurality of elements. For example, the SiGe layer 31 is made of single crystal SiGe (Ge=50%, p+ conductivity type, boron-doped, impurity concentration of 1×10²⁰ cm⁻³) The semiconductor substrate may include an active layer of a Si substrate, a Ge substrate, a silicon on insulator (SOI) substrate, a germanium on insulator (GOI) substrate, or a silicon germanium on insulator (SGOI) substrate.

The Si substrate 10, the oxide layer 20, and the SiGe layer 31 are formed using a SGOI substrate in which the Si substrate 10 is a support substrate, the oxide layer 20 is a buried layer, and the SiGe layer 31 is SGOI layer (active layer). The SiGe layer 31 corresponds to a Si layer in a SOI substrate.

The SiGe layer 31 is covered with an oxide layer 40 made of, for example, SiO₂. The SiGe layer 31 is electrically coupled with an electrode 72 through an opening portion for contact that is provided at a predetermined portion of the oxide layer 40 and is communicated with an opening portion 62 (see FIG. 11). The electrode 72 is made of, for example, aluminum. The SiGe layer 31 has an exposed surface portion that is exposed from the oxide layer 40 through an opening portion 41 for a detecting part (see FIG. 7). On the exposed surface portion of the SiGe layer 31, the QW structural part 50 is disposed. On a front surface of the QW structural part 50, a SiGe layer 32 is disposed The SiGe layer 32 is similar to the SiGe layer 31 and is made of SiGe (Ge=50%, p+ conductivity type, boron-doped). The SiGe layer 32 is electrically coupled with an electrode 71 made of, for example, aluminum. The SiGe layer 31 and the QW structural part 50 will be described in detail below.

An oxide layer 60 covers the oxide layer 20, the SiGe layer 32, the oxide layer 40, and the QW structural part 50, and thereby the QW structural part 50 is protected. The oxide layer 60 has a thickness that is greater than a thickness of the SiGe layer 31, the QW structural part 50, and SiGe layer 32 which are stacked. The oxide layer 60 has opening portions 61 and 62 at positions corresponding to the opening portion provided in the oxide layer 40 and the SiGe layer 32 (see FIG. 11). The electrode 71 is disposed from a front surface of the SiGe layer 31 to a front surface of the oxide layer 60 through the opening portion of the oxide layer 40 and the opening portion 61 of the oxide layer 60. The electrode 72 is disposed from a front surface of the SiGe layer 32 to the front surface of the oxide layer 60 through the opening portion 62 of the oxide layer 60.

On front surfaces of the electrodes 71 and 72, a silicon nitride layer 81 is disposed. The silicon nitride layer 81 has opening portions 81a and 81b for forming pad portions of the electrodes 71 and 72. The temperature sensor 100 is electrically coupled with an external processing circuit (not shown) by wire bonding through the opening portions 81a and 81b. At a position of the silicon nitride layer 81 corresponding to the QW structural part 50, an infrared absorption layer 90 made of carbon paste is disposed.

On the rear surface of the Si substrate 10, a silicon nitride layer (PE-SiN) 82 is formed. The silicon nitride layer 82 has an opening portion 82a communicated with the opening portion 11 of the Si substrate 10.

In the temperature sensor 100, infrared rays that enter from above are absorbed by the infrared absorbing layer 90. By absorbing the infrared rays, the temperature of the membrane increases. The two electrodes 71 and 72 are applied with direct current voltage, and the temperature is detected based on change in electric current that flows in the QW structural part 50. In order to improve a sensitivity of the temperature sensor 100 using the quantum well structural body, it is necessary to increases the value of temperature coefficient of resistance (TCR) of the quantum well structural body. The TCR of the quantum well structural body can be expressed as following equation.

TCR=−1/k_{B}T²×(3k_{B}T/2+E_{f})

where “k_{B}” is the Boltzmann constant, “T [k]” is the absolute temperature, “V (=E_{B}−E_{W})” is a barrier energy, “E_{B}” is an energy at a peak of a valence band (or a bottom of a conduction band) of the barrier layers, “E_{W}” is an energy at a peak of a valence band (or a bottom of a conduction band) of the well layers, and “E_{f}” is a Fermi energy. When the well layers are doped with p type impurities, each of “E_{B}” and “E_{W}” means the peak of the valence band, and when the well layers are doped with n type impurities, each of “E_{B}” and “E_{W}” means the bottom of the conduction band.

As shown in the above equation, it is required to increase the barrier energy “V” or decrease the Fermi energy “E_{f}” in order to increase the value of |TCR|.

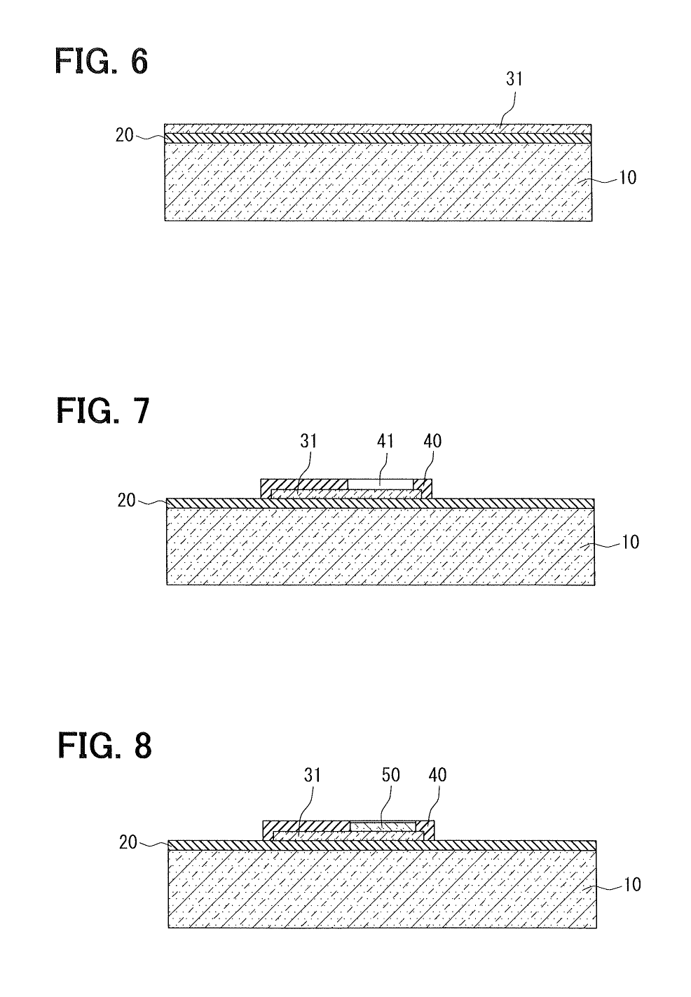

A manufacturing method of the temperature sensor 100 will be described with reference to FIG. 6 to FIG. 12.

During a process shown in FIG. 6, the SGOI substrate including the Si substrate (support substrate) 10, the oxide layer (insulating layer) 20, and the SiGe layer (active layer) 31 is prepared The oxide layer 20 has a thickness of, for example, 1 μm. For example, the SiGe layer 31 is made of single SiGe, (Ge=50%, p conductivity type, boron-doped, impurity concentration of 1×10²⁰ cm⁻³).

During a process shown in FIG. 7, the oxide layer 40 is formed. The oxide layer 40 can function as a mask. The oxide layer 40 has the opening portion 41 extending to the SiGe layer 31 at a position corresponding to the QW structural part 50. In other words, the oxide layer 40 is formed on the front surface of the SiGe layer 31 and has the opening portion 41 extending to the SiGe layer 31 at the position where the QW structural part 50 is formed. Specifically, the SiGe layer 31 is treated with a patterning process in such a manner that at least portions electrically coupled with the QW structural part 50 and the electrode 72 remain. Then, the oxide layer 40 made of, for example, SiO₂ is formed on the front surface of the SiGe layer 31 by a plasma enhanced CVD or a low pressure CVD. Then, the oxide layer 40 is treated with a patterning process so that the opening portion 41 is provided at the position where the QW structural part 50 is formed.

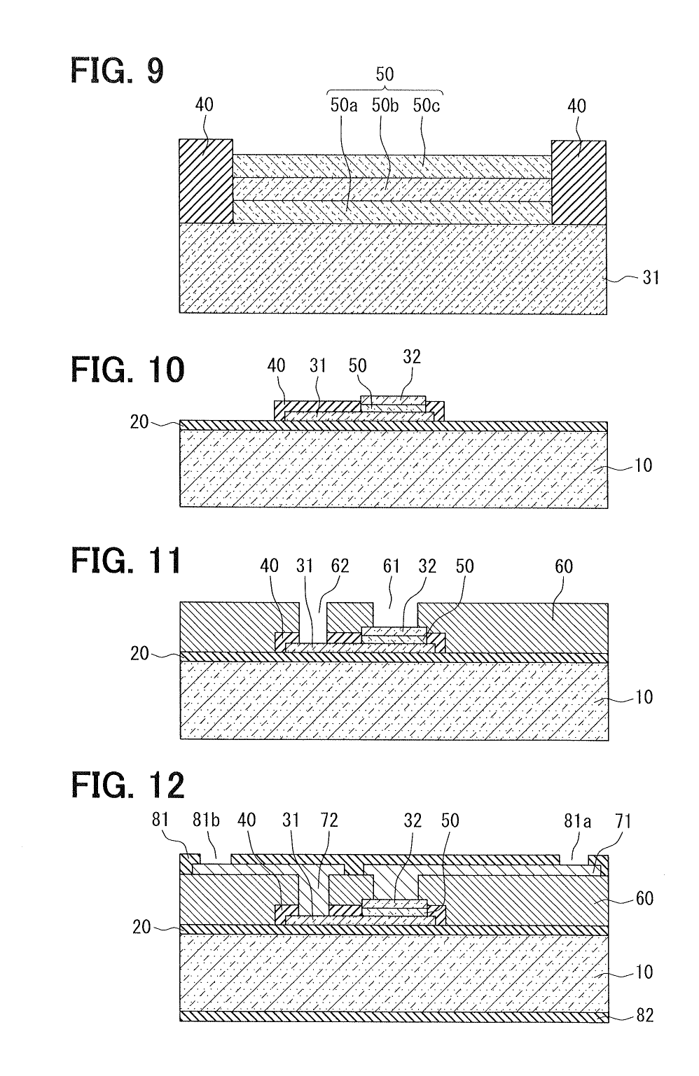

During a process shown in FIG. 8, each layer for forming the QW structural part 50 is selectively formed in the opening portion 41 by epitaxial growth. In other words, on the front surface of the SiGe layer 31 exposed through the opening portion 41, each layer for forming the QW structural part 50 is selectively formed by epitaxial growth. Specifically, as shown in FIG. 9, on the surface of the SiGe layer 31 exposed through the opening portion 41, a barrier layer 50a, a well layer 50b, and a barrier layer 50c are grown in this order from a side of the SiGe layer 31. The barrier layer 50a, the well layer 50b, and the barrier layer 50c form the QW structural part 50. Each of the barrier layers 50a and 50c can function as a quantum barrier layer. The well layer 50b can function as a quantum well layer. The barrier layer 50a is made of single crystal SiGe (Ge=20%, non-doped), the well layer 50b is made of single crystal SiGe (Ge=80%, p conductivity type, boron-doped), and the barrier layer 50c is made of single crystal SiGe (Ge=20%, non-doped). By the above-described method, the temperature sensor 100 having a large value of |TCR| and having a high sensitivity can be manufactured by a simple process without causing a crystal defect.

During a process shown in FIG. 10, the SiGe layer 32 is formed on the front surface of the QW structural part 50. The SiGe layer 32 is made of SiGe (Ge=50%, p+ conductivity type, boron-doped). During a process shown in FIG. 11 the oxide layer 60 is formed. The oxide layer 60 and the oxide layer 40 are treated with a Patterning Process so as to provide the opening portions 61, 62 and to partially expose the SiGe layers 31, 32.

During a process shown in FIG. 12, a layer for forming the electrodes 71, 72 made of, for example, aluminum is formed on the oxide layer 60 having the opening portions 61, 62. The layer for forming the electrodes 71, 72 is treated with a patterning process and thereby the electrodes 71, 72 are formed. Accordingly, the electrodes 71, 72 are formed in the opening portions 61, 62 and on the front surface of the oxide layer 60 and are electrically coupled with the SiGe layers 31, 32. Then, the silicon nitride layer 81 is formed on the electrodes 71, 72 formed on the front surface of the oxide layer 60. The silicon nitride layer (SiN) 81 is treated with a patterning process so as to provide the opening portions 81a, 81b for forming the pad portions of the electrodes 71, 72. Furthermore, the rear surface of the Si substrate 10 is grinded and polished, and the silicon nitride layer (PE-SiN) 82 is formed on the rear surface.

After that, the opening portions 11, 82a are provided in the Si substrate 10 and the silicon nitride layer 82 so that the QW structural part 50 is located above the membrane. For example, the silicon nitride layer 82 and the Si substrate 10 are treated with a wet etching process from a rear surface side of the Si substrate 10 using the oxide layer 20 as an etching stop layer, and thereby the opening portions 11, 82b are provided. In other words, the membrane is formed by wet etching the silicon nitride layer 82 and the Si substrate 10 from a rear surface side of the Si substrate 10. Then, at the position of the silicon nitride layer 81 corresponding to the QW structural part 50, the infrared absorbing layer 90 made of, for example, a carbon paste is formed.

When a quantum well structural infrared detector such as the temperature sensor 100 is manufactured with a CMOS process, there are advantages that circuits can be integrally formed easily and noises can be restricted and that the manufacturing cost can be reduced because the temperature sensor can be manufactured in the conventional semiconductor factory.

When a quantum well structural infrared detector such as the temperature sensor 100 is manufactured with a CMOS process, there are advantages that circuits can be integrally formed easily and noises can be restricted and that the manufacturing cost can be reduced because the temperature sensor can be manufactured in the conventional semiconductor factory.

Next, the QW structural part 50 and the SiGe layer 31 which is a substrate for an epitaxial growth the QW structural part 50 will be described. As shown in FIG. 1, the QW structural part 50 in the temperature sensor 100 is disposed on the front surface of the SiGe layer 31 and is disposed above the membrane formed by providing the opening portion 11 in the Si substrate 10. In the temperature sensor 100, as a substrate for the epitaxial growth of the QW structural part 50, not a Si substrate (Si layer) but a SiGe substrate (SiGe layer 31) is used. Thus, the SiGe layer 31 can function as a substrate for an epitaxial growth of the QW structural part 50. When the QW structural part 50 is formed above the membrane, a heat conductance can be reduced and the sensitivity can be improved.

The QW structural part 50 includes the barrier layers 50a, 50c and the well layer 50b disposed between the barrier layer 50a and the barrier layer 50c. The barrier layer 50a, the well layer 50b, and the barrier layer 50c are stacked in this order in a direction perpendicular to the front surface of the SiGe layer 31.

The barrier layers 50a, 50c are made of a material having a larger band gap than a material of the well layer 50b. Thus, the well layer 50b is made of a material having a smaller band gap than a material of the barrier layers 50a, 50c.

In other words, the barrier layers 50a, 50c and the well layer 50b are formed on the SiGe layer 31 and form the QW structural part 50. The QW structural'part 50 is made of a plurality of semiconductor layers made of the same element as the SiGe layer 31 and has a resistance that changes with temperature. In other words, a plurality of semiconductor layers for forming the QW structural part 50 includes the barrier layers 50a, 50c and the well layer 50b disposed between the barrier layers 50a, 50c.

The temperature sensor 100 according to the present embodiment will be compared with a temperature sensor according to a comparative example. In the temperature sensor according to the comparative example, a Si substrate (Si layer) is used as a substrate for an epitaxial growth of a QW structural part. In the temperature sensor according to the comparative example, on a Si layer (p+ conductivity type, boron-doped) that is an active layer of a SOI substrate, a barrier layer made of Si (non-doped), a well layer made of SiGe (Ge=30° A, p conductivity type, boron-doped), and a barrier layer made of Si (non-doped) are stacked in this order so as to form the QW structural part. Thus, the Si layer (p+) in the comparative example corresponds to the SiGe layer 31 in the present embodiment, the barrier layers made of Si (non-doped) in the comparative example corresponds to the barrier layers 50a, 50c in the present embodiment, and the well layer made of SiGe layer (Ge=30%) in the comparative example corresponds to the well layer 50b in the present embodiment. Furthermore, in the temperature sensor according to the comparative example, a Si layer (p+ conductivity type, boron-doped) corresponds to the SiGe layer 32 in the present embodiment is disposed on the QW structural part. The other configuration of the temperature sensor according to the comparative example is similar to the temperature sensor 100 according to the present embodiment.

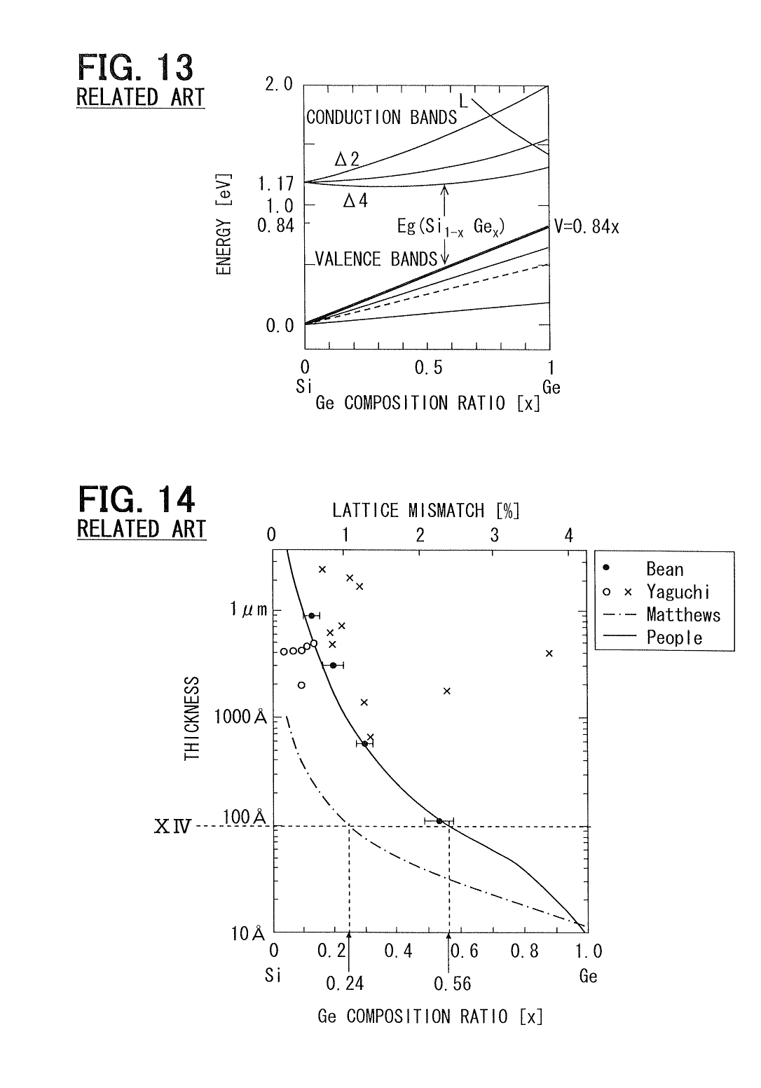

When a material system of SiGe/Si is used, a quantum well generally includes p type doped SiGe and non-doped Si. This is because the barrier height of the valence band is larger than the barrier height of the conduction band in this system. As shown in FIG. 13, when a Ge composition ratio in SiGe is indicated by “x,” the barrier height “V” of the valence band can be expressed as V=0.84×[eV] Thus, when the Ge composition ratio in SiGe increases, the barrier height increases, and the value of TCR increases.

In an epitaxial growth of SiGe on Si, there is a critical thickness. Thus, it is difficult to increase the Ge composition ratio freely. When the thickness of SiGe is greater than the critical thickness, a crystal defect is generated for relaxing a strain in SiGe.

As shown in FIG. 14, regarding the critical thickness of SiGe, two theories by Matthews et al. and People et al. are known. A thickness of SiGe suitable for a temperature sensor including a QW structural part, that is, a quantum well structural infrared detector is about 10 nm (100 Å). Thus, the Ge composition ratio with which the SiGe can grow without causing a crystal defect is 0.24 (from the theory by Matthews et al.) or 0.56 (from the theory by People et al.), and the most effective value x=1 cannot be realized.

In the temperature sensor 100 according to the present embodiment, the SiGe layer 31 is used as a substrate for the epitaxial growth of the QW structural part 50. Thus, the Ge composition ratio of the barrier layers 50a, 50c can be lower than the Ge composition of the SiGe layer 31, and the Ge composition ratio of the well layer 50b can be higher than the Ge composition of the SiGe layer 31. In the present embodiment, the SiGe layer 31 is made of SiGe (Ge=50%, p+ conductivity type, boron-doped). Thus, for example, the barrier layers 50a, 50c may be made of SiGe (Ge=20%, non-doped) and the well layer 50b may be made of SiGe (Ge-=80%, p conductivity type, boron-doped). Because the Ge composition ratio of the substrate for the epitaxial growth of the QW structural part 50 is between the Ge composition ratio of the barrier layer and the Ge composition ratio of the well layer, the Ge composition ratio of the SiGe layer 31 may be from 30% to 70%.

The Ge composition ratios of the well layer 50b and the barrier layers 50a, 50c are merely examples. In a case where Si(1−x)Gex (0<x<1, x:Ge composition ratio in SiGe) is used as materials of the QW structural part 50 and the substrate for the epitaxial growth of the QW structural part 50, the object can be achieved as long as the Ge composition ratio of the well layer 50b is higher than the Ge composition ratio of the SiGe layer 31, and the Ge composition ratio of the barrier layers 50a, 50c is lower than the Ge composition ratio of the SiGe layer 31. Thus, when SiGe is used as material of the QW structural part 50 and the substrate for the epitaxial growth of the QW structural part 50, each of the Ge composition ratios may be changed within a range satisfying the above-described relationship. In the present case, Si corresponds to an element E₁ and Ge corresponds to an element E₂

In addition, in a case where Si(1−x)Gex (0<x<1, x:Ge composition ratio in SiGe) is used as materials of the QW structural part 50 and the substrate for the epitaxial growth of the QW structural part 50, the object can be achieved as long as a lattice constant “c” of the well layer 50b is larger than the lattice constant “a” of the SiGe layer 31, and the lattice constant “b” of the barrier layers 50a, 50c is smaller than the lattice constant “a” of the SiGe layer 31, that is, a relationship of b<a<c is satisfied. In other words, the object can be achieved as long as the lattice constants of the substrate for the epitaxial growth of the QW structural part, the well layer, and the barrier layers satisfy a relationship of (barrier layers)<(substrate)<(well layer). The above-described lattice constants are lattice constants in a state where a strain is not generated.

In the temperature sensor according to the comparative example, there is no constant mismatch in the barrier layers because the barrier layers have the same composition as the substrate. In the well layers, (lattice mismatch)=(a_{SiGe}−a_{Si})/a_{Si}, where a lattice constant a_{Si}=5.43 Å, a lattice constant a_{Ge}=5.65 Å, and a lattice constant a_{SiGe}=(1−x)·a_{Si}+x·a_{Ge}. Thus, the lattice mismatch is 1.22%.

In the temperature sensor 100 according to the present embodiment, a lattice mismatch of the barrier layers 50a, 50c is (lattice mismatch)=(a_{SiGe(Ge=20%)}−a_{SiGe(Ge=50%)})/a_{SiGe(Ge=50%)}, and a lattice mismatch of the well layer 50b is (lattice mismatch)=a_{SiGe(Ge=80%)}−a_{SiGe(Ge=50%)})/a_{SiGe(Ge=80%)}. Thus, the lattice mismatch of the barrier layers 50a, 50c is −1.19%, and the lattice mismatch of the well layer 50b is 1.19%. In this way, in the present embodiment, the lattice mismatches can be smaller than the comparative example. Therefore, the critical thickness of SiGe can be increased.

When the substrate for the epitaxial growth of the QW structural part is used as a basis, in the temperature sensor according to the comparative example, the lattice mismatch is generated in only one direction (+side). In contrast, in the temperature sensor 100 according to the present embodiment, the lattice mismatches are generated on an upper side and a lower side (+side and −side). As described above, in the temperature sensor 100 according to the present embodiment, the Ge composition ratios of the barrier layers 50a, 50c and the well layer 50b can be higher and lower than the'Ge composition ratio of the substrate (the SiGe layer 31). Because the difference in the Ge composition ratio between the barrier layers 50a, 50c and the well layer 50b can be increased, the barrier heights V (energy) of the barrier layers 50a, 50c can be increased compared with the comparative example. Specifically, the barrier height V of the temperature sensor according to the comparative example is V=0.252 [eV], and the barrier height V of the temperature sensor 100 according to the present embodiment can be V=0.504 [eV]. Thus, the temperature sensor 100 according to the present embodiment can increase the barrier height V (energy) of the barrier layers 50a, 50c compared with the temperature sensor according to the comparative example.

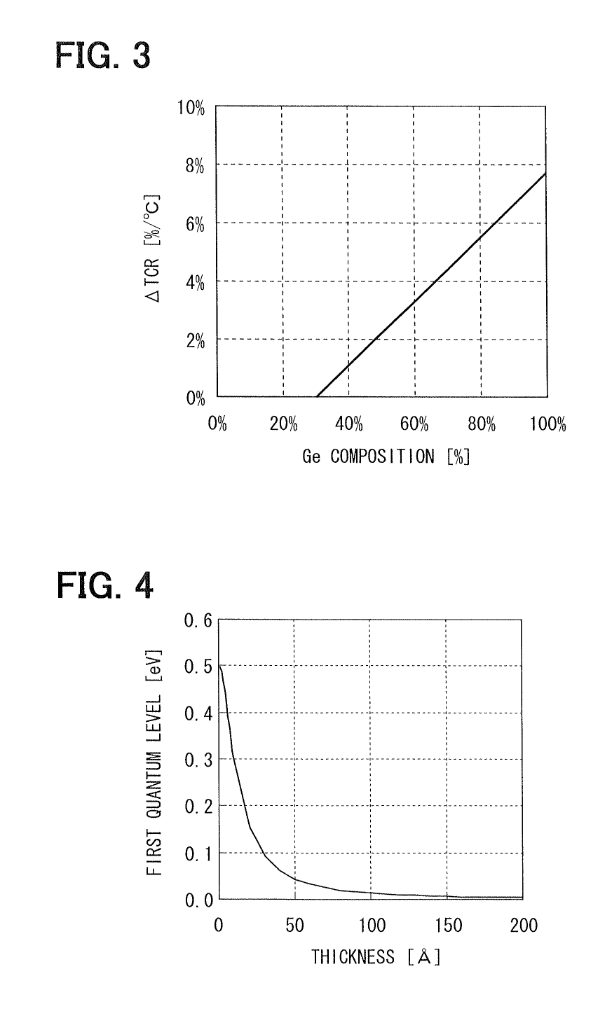

Therefore, the temperature sensor 100 according to the present embodiment can increase the value of |TCR| with restricting generation of a crystal defect. A graph in FIG. 3 shows an improvement of TCR with respect to the difference in the Ge composition ratio between the barrier layers 50a, 50c and the well layer 50b.

The thickness of the well layer 50b in the QW structural part 50 may be equal to or greater than 4 nm (40 Å). The thickness of the well layer 50b is a thickness in a direction perpendicular to the SiGe layer 31, that is, a thickness in a stacking direction of the well layer 50b.

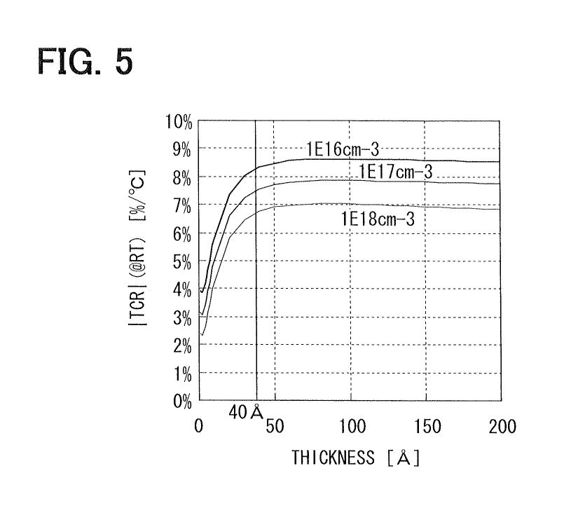

This point will be described below. The value of TCR of a quantum well structural body such as QW structural part 50 is high when the Fermi level is low. The Fermi level is low when the first quantum level is low. For simulation results shown in FIG. 4 and FIG. 5, it is found that the first quantum level is close to zero (the bottom of the well) and the value of TCR is saturated when the thickness of the well layer 50b is equal to or greater than 4 nm (40 Å). Thus, the thickness of the well layer 50b in the QW structural part 50 may be, equal to or greater than 4 nm (40 Å). FIG. 4 and FIG. 5 show the simulation results in a case where the Ge composition ratios of the substrate, the well layer, and the barrier layers are 50%, 80%, and 20%, respectively.

### Other Embodiments

Although the present invention has been fully described in connection with the preferred embodiments thereof with reference to the accompanying drawings, it is to be noted that various changes and modifications will become apparent to those skilled in the art.

In the above-described embodiment, the QW structural part 50 has a single QW structure including the barrier layers 50a, 50c and the well layer 50b disposed between the barrier layers 50a, 50c, as an example. The QW structural part 50 may also have a multi quantum well (MQW) structure in which a barrier layer and a well layer are stacked in this order in a repetitive manner.

In the above-described embodiment, SiGe is used as the material of the QW structural part 50 and the material of the substrate for the epitaxial growth of the QW structural part 50, as an example. The material of the QW structural part 50 and the material of the substrate for the epitaxial growth of the QW structural part 50 are not limited to SiGe. The material of the QW structural part 50 and the material of the substrate for the epitaxial growth of the QW structural part 50 may be a semiconductor material made of a plurality of elements including an element E₁ and an element E₂, and the elements E₁ and E₂ satisfy a relationship of E₁(1−x)E₂x (0<x<1, x:E₂ composition ratio in the semiconductor material). For example, GaAs and AlGaAs may be used. GaAs has a band gap of 1.42 eV, and AlGaAs has a band gap of from 1.42 eV to 2.17 eV (AlAs has a band gap of 2.17 eV). Thus, GaAs provides a well layer, and AlGaAs provides a barrier layer. GaAs has a lattice constant of 5.653 Å and AlGaAs has a lattice constant of from 5.653 Å to 5.661 Å (AlAs has a lattice constant of 5.661 Å).

In the present case the lattice constants of the substrate for the epitaxial growth of the QW structural part 50, the well layer, and the barrier layer have a relationship of (well layer)<(substrate)<(barrier layer). In other words, when the lattice constant of the substrate for the epitaxial growth of the QW structural part 50 is “a,” the lattice constant of the barrier layer is “b,” and the lattice constant of the well layer is “c,” the object of the present invention can be achieved when the lattice constants satisfy a relationship of c<a<b.

In the above-described embodiment, because the SiGe layer 31 is used as the substrate for the epitaxial growth of the QW structural part 50, SiGe having a lower Ge composition ratio than the SiGe layer 31 is used for the barrier layers 50a and 50c, and SiGe having a higher Ge composition ratio than the SiGe layer 31 is used for the well layer 50b. The materials of the substrate, the barrier layers, and the well layer are not limited to the above-described examples. In a material system other than SiGe, with respect to the E₂ composition ratio of the substrate for the epitaxial growth of the QW structural part 50, a semiconductor layer having a higher E₂ composition ratio may be used for a quantum barrier layer, and a semiconductor layer having a lower E₂ composition ratio may be used for a quantum well layer. The above-described material system of GaAs and AlGaAs is one such example.

Finally, various aspects of the present invention will be described below. A temperature sensor according to a first aspect of the present invention includes a semiconductor substrate and a quantum well structural part disposed on the semiconductor substrate. The semiconductor substrate is made of a plurality of elements The quantum well structural part has a resistance value that changes with temperature. The quantum well structural part includes a plurality of semiconductor layers made of the elements. The semiconductor layers include a plurality of quantum barrier layers and a quantum well layer disposed between the quantum barrier layers. When the semiconductor substrate has a lattice constant “a,” each of the quantum barrier layers has a lattice constant “b,” and the quantum well layer has a lattice constant “c,” the semiconductor substrate, the quantum barrier layers, and the quantum well layer satisfy a relationship of b<a<c or c<a<b.

In the above-described temperature sensor, when the quantum barrier layers and the quantum well layer are epitaxially formed on the semiconductor substrate, lattice mismatches of the quantum barrier layers and the quantum well layer can be generated on both an upper side and a lower side (+side and −side) while restricting generation of a crystal defect. When lattice mismatches are generated on the upper side and the lower side (+side and −side), compared with a case where lattice mismatches are generated on only one side, an energy difference (barrier height) between the quantum barrier layers and the quantum well layer can be increased without increasing the absolute values of the lattice mismatches. Thus, the temperature sensor can increase the value of |TCR| and can have a high sensitivity while restricting generation of a crystal defect.

In a case where, for example, SiGe is used as a material of the semiconductor substrate, the quantum barrier layers, and the quantum well layer, each of the quantum barrier layers may have a lower lattice constant and the quantum well layer may have a higher lattice constant than a lattice constant of the semiconductor substrate. In a case where, for example, GaAs and AlGaAs are used as materials of the semiconductor substrate, the quantum barrier layers, and the quantum well layer, each of the quantum barrier layers may have a higher lattice constant and the quantum well layer may have a lower lattice constant than a lattice constant of the semiconductor substrate.

In the semiconductor device according to the first aspect, the semiconductor substrate, the quantum barrier layers, and the quantum well layer may be made of SiGe.

SiGe is a material compatible with CMOS. Thus, when the semiconductor substrate, the quantum barrier layers, and the quantum well layer are made of SiGe, a circuit can be integrally formed easily, and noises can be restricted. Furthermore, because the temperature sensor can be formed in a conventional semiconductor factory, a manufacturing cost can be reduced.

In a case where the elements include an element E₁ and an element E₂₁ each of the quantum barrier layers may have a lower E₂ composition ratio and the quantum well layer may have a higher E₂ composition ratio than an E₂ composition ratio of the semiconductor substrate. Alternatively, each of the quantum barrier layers may have a higher E₂ composition ratio and the quantum well layer may have a lower E₂ composition ratio than the E₂ composition ratio of the semiconductor substrate.

Accordingly, the E₂ composition ratios of the quantum barrier layers and the quantum well layer can be higher and lower than the E₂ composition ratio of the semiconductor substrate. Thus, compared with a case where the E₂ composition ratios of the quantum barrier layers and the quantum well layer can be higher or lower than the E₂ composition ratio of the semiconductor substrate, the energy difference (barrier height) between the quantum barrier layers and the quantum well layer can be increased.

Each of quantum barrier layers and the quantum well layer may have a thickness less than or equal to a critical thickness.

Accordingly, because generation of a crystal defect can be restricted, noises of the temperature sensor can be reduced. Thus, the temperature sensor can improve a specific detectivity.

The quantum well layer may have a thickness of equal to or greater than 4 nm (40 Å).

Accordingly, the value of |TCR| can be increased.

The temperature sensor according to the first aspect may further include a membrane, and the quantum well structural Part may be disposed above the membrane.

Accordingly, a heat conductance can be reduced. Thus, the temperature sensor can improve sensitivity. In other words, because a heat emission from the quantum well structural part can be reduced, the temperature sensor can improve a specific detectivity.

A manufacturing method according to a second aspect of the present invention is a manufacturing method of a semiconductor device that includes semiconductor substrate and a quantum well structural part disposed on the semiconductor substrate, in which the semiconductor substrate is made of a plurality of elements including an element E₁ and an element E₂, the quantum well structural part has a resistance value that changes with temperature, the quantum well structural part includes a plurality of semiconductor layers made of the plurality of elements, and the plurality of semiconductor layers includes a plurality of quantum barrier layers and a quantum well layer disposed between the plurality of quantum barrier layers, the manufacturing method includes epitaxially growing the plurality of quantum barrier layers and the quantum well layer on the semiconductor substrate in such a manner that each of the quantum barrier layers has a lower E₂ composition ratio and the quantum well layer has a higher E₂ composition ratio than an E₂ composition ratio of the semiconductor substrate.

By the above-described method, a temperature sensor in which an energy difference between the quantum barrier layers and the quantum well layer (barrier height) is large can be manufactured. In other words, a temperature sensor having a high sensitivity can be manufactured.

A manufacturing method according to a third aspect of the present invention is a manufacturing method of a semiconductor device that includes semiconductor substrate and a quantum well structural part disposed on the semiconductor substrate, in which the semiconductor substrate is made of a plurality of elements including an element E₁ and an element E₂, the quantum well structural part has a resistance value that changes with temperature, the quantum well structural part includes a plurality of semiconductor layers made of the plurality of elements, and the plurality of semiconductor layers includes a plurality of quantum barrier layers and a quantum well layer disposed between the plurality of quantum barrier layers, the manufacturing method includes epitaxially growing the plurality of quantum barrier layers and the quantum well layer on the semiconductor substrate in such a manner that each of the quantum barrier layers has a higher E₂ composition ratio and the quantum well layer has a lower E₂ composition ratio than an E₂ composition ratio of the semiconductor substrate.

Also by the manufacturing method according to the third aspect, temperature sensor in which an energy difference between the quantum barrier layers and the quantum well layer (barrier height) is large can be manufactured. In other words, a temperature sensor having a high sensitivity can be manufactured.

The manufacturing method according to the second aspect or the third aspect may further include forming a mask on the semiconductor substrate, in which the mask may have an opening portion at a position where the quantum well structural part is formed, and the epitaxially growing the quantum barrier layers and the quantum well layer may be performed through the opening portion.

In the present case, an etching process of the quantum barrier layers and the quantum well layer for patterning is not required. Because an etching process of the quantum barrier layers and the quantum well layer is not required it can be restrict that a thickness of the semiconductor substrate is reduced by over etching or the semiconductor substrate is fully etched. In general, the semiconductor substrate is a thin layer such as an active layer of a SGOI substrate. Using this active layer, an electric potential of a lower electrode of the quantum well structural part is pulled out from a different position of the quantum well structural part on the semiconductor substrate. Thus, if the thickness of the active layer is reduced or the active layer is fully etched by over etching, resistance value is increased and the electric potential of the lower electrode cannot be detected with accuracy. When the quantum barrier layers and the quantum well layer are epitaxially grown through the opening portion of the mask, the above-described problem can be prevented.

The manufacturing method according to the second aspect or the third aspect may further include forming the semiconductor substrate above a support substrate through an insulating layer, and forming a membrane by etching a portion of the support substrate located under the quantum structural part using the insulating layer as an etching stop layer.

Accordingly a heat conductance can be reduced. Thus, a temperature sensor having a high sensitivity can be manufactured. In other words, because a heat emission from the quantum well structural part can be reduced, a temperature sensor having a high specific detectivity can be manufactured.

What is claimed is:

1. A temperature sensor comprising:
a semiconductor substrate made of a plurality of elements; and
a quantum well structural part disposed on the semiconductor substrate, the quantum well structural part having a resistance value that changes with temperature, the quantum well structural part including a plurality of semiconductor layers made of the plurality of elements, the plurality of semiconductor layers including a plurality of quantum barrier layers and a quantum well layer disposed between the plurality of quantum barrier layers, wherein
when the semiconductor substrate has a lattice constant “a,” each of the plurality of quantum barrier layers has a lattice constant “b,” and the quantum well layer has a lattice constant “c,” the semiconductor substrate, the plurality of quantum barrier layers, and the quantum well layer satisfy a relationship of b<a<c or c<a<b.

2. The temperature sensor according to claim 1, wherein
the semiconductor substrate, the plurality of quantum barrier layers, and the quantum well layer are made of SiGe.

3. The temperature sensor according to claim 1, wherein
the plurality of elements includes an element E₁ and an element E₂, and
each of the plurality of quantum barrier layers has a lower E₂ composition ratio and the quantum well layer has a higher E₂ composition ratio than an E₂ composition ratio of the semiconductor substrate.

4. The temperature sensor according to claim 1, wherein
the plurality of elements includes an element E₁ and an element E₂, and
each of the plurality of quantum barrier layers has a higher E₂ composition ratio and the quantum well layer has a lower E₂ composition ratio than an E₂ composition ratio of the semiconductor substrate.

5. The temperature sensor according to claim 1, wherein
each of the plurality of quantum barrier layers and the quantum well layer has a thickness of less than or equal to a critical thickness.

6. The temperature sensor according to claim 1, wherein
the quantum well layer has a thickness of equal to or greater than 4 nm.

7. The temperature sensor according to claim 1, further comprising a membrane, wherein the quantum well structural part is disposed above the membrane.

8. A manufacturing method of a temperature sensor that includes a semiconductor substrate and a quantum well structural part disposed on the semiconductor substrate wherein the semiconductor substrate is made of a plurality of elements including an element E₁ and an element E₂, the quantum well structural part has a resistance value that changes with temperature, the quantum well structural part includes a plurality of semiconductor layers made of the plurality of elements, and the plurality of semiconductor layers includes a plurality of quantum barrier layers and a quantum well layer disposed between the plurality of quantum barrier layers, the manufacturing method comprising
epitaxially growing the plurality of quantum barrier layers and the quantum well layer on the semiconductor substrate in such a manner that each of the plurality quantum barrier layers has a lower E₂ composition ratio and the quantum well layer has a higher E₂ composition ratio than an E₂ composition ratio of the semiconductor substrate.

9. A manufacturing method of a temperature sensor that includes a semiconductor substrate and a quantum well structural part disposed on the semiconductor substrate, wherein the semiconductor substrate is made of a plurality of elements including an element E₁ and an element E₂, the quantum well structural part has a resistance value that changes with temperature, the quantum well structural part includes a plurality of semiconductor layers made of the plurality of elements, and the plurality of semiconductor layers includes, a plurality of quantum barrier layers and a quantum well layer disposed between the plurality of quantum barrier layers, the manufacturing method comprising
epitaxially growing the plurality of quantum barrier layers and the quantum well layer on the semiconductor substrate in such a manner that each of the plurality quantum barrier layers has a higher E₂ composition ratio and the quantum well layer has a lower E₂ composition ratio than an E₂ composition ratio of the semiconductor substrate.

10. The manufacturing method according to claim 8, further comprising forming a mask on the semiconductor substrate, wherein
the mask has an opening portion at a position where the quantum well structural part is formed and
the epitaxially growing the plurality of quantum barrier layers and the quantum well layer is performed through the opening portion.

11. The manufacturing method according to claim 8, further comprising
forming the semiconductor substrate above a support substrate through an insulating layer, and
forming a membrane by etching a portion of the support substrate located under the quantum well structural part using the insulating layer as an etching stop layer.
